(19) United States
(12) Patent Application Publication
(10) Pub. No.: US 2020/0403599 A1
(43) Pub. Date: Dec. 24, 2020

(54) ACOUSTIC WAVE ELEMENT

(71) Applicant: KYOCERA Corporation, Kyoto-shi, Kyoto (JP)

(72) Inventors: Motoki ITO, Ikoma-shi, Nara (JP); Tetsuya KISHINO, Nara-shi, Nara (JP)

(21) Appl. No.: 16/971,551

(22) PCT Filed: Feb. 20, 2019
(86) PCT No.: PCT/JP2019/006387

§ 371 Date: Aug. 20, 2020

(30) Foreign Application Priority Data
Feb. 26, 2018 (JP) 2018-031760

(51) Int. Cl. H03H 9/02

(52) U.S. Cl. CPC H03H 9/02574; H03H 9/02559

(57) ABSTRACT

An acoustic wave element includes an IDT electrode which includes a plurality of electrode fingers and excites a surface acoustic wave, a first substrate on an upper surface of which the IDT electrode is located, has a thickness less than 2 times “p” of a repetition interval of the plurality of electrode fingers, and is made of a piezoelectric crystal, an intermediate layer which includes a first surface and a second surface, has the first surface joined to a lower surface of the first substrate, and is made of a material having a slower transverse wave acoustic velocity than the first substrate, and a second substrate made of sapphire which is joined to the second surface.

### TECHNICAL FIELD

The present invention relates to an acoustic wave element.

### BACKGROUND ART

Conventionally, it has been known to bond a support substrate and a piezoelectric substrate to each other to form a composite substrate for the purpose of improving the electrical characteristics and provide electrodes on it to prepare an acoustic wave element. Here, the acoustic wave element is used as for example a bandpass filter in a mobile phone or another communication device. Further, as the composite substrate, there is known one using lithium niobate or lithium tantalate as the piezoelectric substrate and using silicon, quartz, a ceramic, or the like as the support substrate (see Japanese Patent Publication No. 2006-319679A).

### SUMMARY OF INVENTION

### Technical Problem

However, in recent years, portable terminal devices used in mobile communications have been made increasingly smaller in size and lighter in weight. In addition, in order to realize a high quality of communication, an acoustic wave element provided with further higher electrical characteristics has been demanded. For example, an acoustic wave element having little variation in frequency characteristics has been demanded.

The present invention was made in consideration with such a technical problem and has as an object thereof to provide an acoustic wave element excellent in electrical characteristics.

### Solution to Problem

An acoustic wave element of the present disclosure includes an IDT electrode, a first substrate, an intermediate layer, and a second substrate. The IDT electrode includes a plurality of electrode fingers and excites a surface acoustic wave. The first substrate is one configured by a piezoelectric crystal, includes an upper surface on which the IDT electrode is located, and has a thickness of less than 2 times a repetition interval “p” of the plurality of electrode fingers. The intermediate layer includes a first surface and a second surface, has the first surface joined to the lower surface of the first substrate, and is comprised of a material having a transverse wave acoustic velocity slower than the first substrate and the second substrate. The second substrate is sapphire joined to the second surface.

### Advantageous Effect of Invention

According to the above configuration, an acoustic wave element excellent in electrical characteristics can be provided.

### BRIEF DESCRIPTION OF DRAWINGS

FIG. 1A is an upper surface view of a composite substrate according to the present disclosure, and FIG. 1B is a partially cutaway perspective view of FIG. 1A.

FIG. 2 is an explanatory diagram of an acoustic wave element according to the present disclosure.

FIG. 3 is a graph showing the relationships between material parameters of a second substrate and the frequency change ratio of a SAW element.

FIG. 4 is a graph showing relationships between the thickness of the first substrate and a resonance frequency.

FIG. 5 is a contour map showing the relationships between the thickness of the first substrate and the thickness of an intermediate layer 50 and the frequency change ratio.

FIG. 6A to FIG. 6C are graphs each showing a correlation between the thickness of the intermediate layer and an amount of shift of the resonance frequency.

FIG. 7 is a graph showing a state of change of frequency with respect to the thickness of an acoustic wave element according to a reference example.

### DESCRIPTION OF EMBODIMENTS

Below, one example of a composite substrate and acoustic wave element of the present disclosure will be explained in detail by using the drawings.

(Composite Substrate)

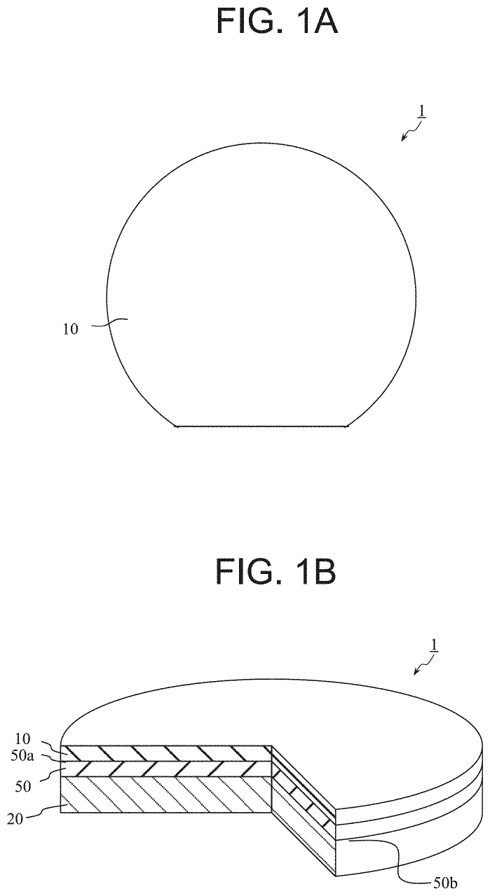

A composite substrate 1 in the present embodiment, as shown in FIGS. 1A and 1B, is a so-called bonded substrate and is configured by a first substrate 10, a second substrate 20, and an intermediate layer 50 positioned between the first substrate 10 and the second substrate 20. Here, FIG. 1A is an upper surface view of the composite substrate 1, and FIG. 1B is a perspective view showing cutaway part of the composite substrate 1.

The first substrate 10 is made of a piezoelectric material and is configured by for example a substrate of a single crystal having a piezoelectric characteristic made of lithium tantalate (LiTaO₃, below, referred to as “LT”) crystal. Specifically, for example, the first substrate 10 is configured by a 36° to 60° Y-cut and X-propagated LT substrate. Use may be made of lithium niobate crystal as well. In this case, for example, it may be 60° to 70° Y-cut as well.

The thickness of the first substrate 10 is substantially constant in the plane and is designed so as to become less than 2 times the pitch “p”. Here, the pitch “p” shows the repetition interval of electrode fingers 32 configuring an IDT electrode 31 explained later. More specifically, it shows the interval between the centers of the electrode fingers 32 in the width direction. Further, the total thickness of the first substrate 10 and a later explained intermediate layer 50 may be also less than 2p. The planar shape and various dimensions of the first substrate 10 may also be suitably set. Note that, in this example, an X-axis of the LT substrate and the direction of propagation of the surface acoustic wave (SAW) substantially coincide.

The second substrate 20 is one supporting the thin first substrate 10, and is made of a material thicker and higher in strength than the first substrate 10. Further, it may be formed by a material having a smaller thermal expansion coefficient than the material of the first substrate 10. In this case, if there is a temperature change, a thermal stress is generated in the first substrate 10. At this time, the temperature dependency and the stress dependency of the elastic constant are cancelled out by each other and in turn the change of the electrical characteristics of the acoustic wave element (SAW element) due to the temperature is suppressed.

Further, the second substrate 20 is made of a material with a higher acoustic velocity of the transverse bulk wave propagating in the second substrate 20 compared with the transverse bulk wave propagating in the first substrate 10. The reason for this will be explained later.

As such a second substrate 20, in the present disclosure, use is made of a sapphire substrate.

The thickness of the second substrate 20 is for example constant and may be suitably set. However, the thickness of the second substrate 20 is set by considering the thickness of the first substrate 10 so that temperature compensation can be suitably carried out. Further, the first substrate 10 in the present disclosure is very thin, therefore the second substrate 20 is made a thickness thick enough to support the first substrate 10. As an example, it may be made 10 times or more of the thickness of the first substrate 10. The thickness of the second substrate 15 is 20 to 300 μm. The planar shape and various dimensions of the second substrate 20 may be made equal to those of the first substrate 10 or may be larger than the first substrate 10.

Further, for the purpose of improving the strength of the substrate as a whole, preventing warping due to thermal stress, and applying a stronger thermal stress to the first substrate 10, a not shown third substrate having a larger thermal expansion coefficient than the second substrate 20 may be bonded to the surface of the second substrate 20 on the side opposite to the first substrate 10 as well. As the third substrate, when the second substrate 20 is made of Si, use can be made of a ceramic substrate, Cu layer, resin substrate, or the like. Further, when the third substrate is provided, the second substrate 20 may be made thin as well.

The intermediate layer 50 is positioned between the first substrate 10 and the second substrate 20. The intermediate layer 50 is provided with a first surface 50a and a second surface 50b which face each other. The first surface 50a is joined to the first substrate 10, and the second surface 50b is joined to the second substrate 20.

The material forming the intermediate layer 50 is configured by a material with an acoustic velocity of the transverse wave of the bulk wave slower than that of the first substrate 10. Specifically, when the first substrate 10 is configured by an LT substrate and the second substrate 20 is configured by sapphire, the material can be made silicon oxide, tantalum oxide, titanium oxide, or the like.

Such an intermediate layer 50 may be formed by formation of a film on the first substrate 10 or on the second substrate 20. Specifically, the intermediate layer 50 is formed on the first substrate 10 or second substrate 20 formed as the support substrate by MBE (molecular beam epitaxy), ALD (atomic layer deposition), CVD (chemical vapor deposition), sputtering, vapor deposition, or the like. After a while, the upper surface of the intermediate layer 50 and the remaining substrate (10 or 20) may be bonded to each other by activating them by plasma, an ion gun, a neutron gun, or the like, then adhering them without a bonding layer interposed, that is, by so-called direct bonding.

The crystallinity of such an intermediate layer 50 can be suitably freely selected from among amorphous, polycrystalline, and the like. Note that, the thickness of the intermediate layer 50 will be explained later.

(SAW Element)

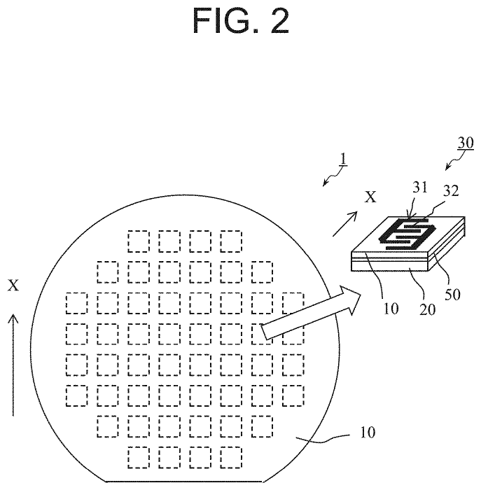

Further, the composite substrate 1 is divided into a plurality of sections as shown in FIG. 2. Each of the sections becomes a SAW element 30. Specifically, the composite substrate 1 is cut into pieces for the individual sections to form the SAW elements 30. In each SAW element 30, an IDT electrode 31 exciting the SAW is formed on the upper surface of the first substrate 10. The IDT electrode 31 has pluralities of electrode fingers 32. The SAW is propagated along the direction of arrangement of the same. Here, this arrangement direction is substantially parallel to the X-axis of the piezoelectric crystal of the first substrate 10.

By using the composite substrate 1, the SAW element 30 can suppress the change of frequency characteristics (electrical characteristics) due to a temperature change.

Further, in the SAW element 30, the first substrate 10 is thin, and the second substrate 20 is bonded to it with the intermediate layer 50 interposed therebetween. According to such a configuration, in the SAW element 30, the bulk wave is reflected at the lower surface of the first substrate 10 or the upper surface of the second substrate 20 and is input to the IDT electrode 31 again, whereby a ripple called a bulk wave spurious emission is generated at a specific frequency.

The bulk wave spurious emission becomes conspicuous particularly in a case where the acoustic velocity of the bulk wave in the second substrate 20 is faster than the acoustic velocity of the bulk wave propagating through the first substrate 10 (case where the first substrate 10 is LT or LiNbO₃ or the like, and the second substrate 20 is sapphire or Si or the like). This is because the bulk wave is sealed in the first substrate 10 due to a difference of acoustic velocities, the first substrate 10 operates as if it were a waveguide making the bulk wave propagate, and that bulk wave and the IDT electrode 31 are coupled at the specific frequency.

Here, the frequency of generation of the bulk wave spurious emission shifts to a higher frequency side as the first substrate 10 becomes thinner. In a region less than 2p, it no longer exists in the resonance frequency and the vicinity of antiresonance frequency. In the SAW element 30 in the present disclosure, the thickness of the first substrate 10 becomes less than 2p even if the intermediate layer 50 is included, therefore reduction of the resonance characteristic due to the bulk wave spurious emission can be suppressed.

Further, when making the thickness of the first substrate 10 1.6p or less, bulk wave spurious emission can be suppressed in the vicinities of the both of the resonance frequency and antiresonance frequency. Due to this, a SAW element 30 suppressing the influence of the bulk wave spurious emission can be provided.

Further, when the thickness of the first substrate 10 is made 0.4p to 1.2p, bulk wave spurious emission is not generated even in a further higher frequency band, therefore a SAW element 30 provided with excellent electrical characteristics can be provided.

Note that, when the first substrate 10 is thinner than 0.4p, the difference between the resonance frequency fr and the antiresonance frequency fa (frequency difference fa−fr) becomes small. For this reason, in order to realize stable frequency characteristics, the thickness of the first substrate 10 may be made 0.4p or more as well.

On the other hand, the thickness of the first substrate 10 is preferably thin for raising the Q value of the SAW element 30. Specifically, the thickness may be made less than 1p as well.

For reference, a SAW element 30 with the first substrate 10 made thinner is disclosed in for example Japanese Patent Publication No. 2004-282232A, Japanese Patent Publication No. 2015-73331A, and Japanese Patent Publication No. 2015-92782A.

In this way, by making the first substrate 10 thin, an SAW element 30 excellent in electrical characteristics can be provided. On the other hand, however, the frequency characteristics of the SAW element 30 end up being influenced by the thickness of the first substrate 10. Further, the total thickness of the first substrate 10 and the intermediate layer 50 is thinner than the wavelength, therefore a portion of the SAW ends up arriving at the second substrate 20 as well. For this reason, the SAW element 30 is influenced by the characteristics of the material of the second substrate 20.

First, the influence by the second substrate 20 will be studied. The thickness of the first substrate 10 is less than 2p, so becomes a thickness less than the wavelength of the SAW, therefore a portion of the SAW ends up being distributed in the second substrate 20. Here, when the SAW is distributed in a material having a low resistivity, the Q value of the SAW element 30 falls. For this reason, the second substrate 20 must be provided with a high insulation property. Therefore, because of its high insulation property, use will be made of a sapphire substrate as the material of the second substrate 20.

Further, the sapphire substrate has a fast acoustic velocity, therefore the bulk wave spurious emission which is positioned on a higher frequency side than the passing band can be positioned on a high frequency side compared with Si or another substrate. From this fact as well, it is possible to provide a SAW element 30 suppressed in bulk wave spurious emission by using a sapphire substrate as the second substrate 20.

Next, the influence of the thickness of the first substrate 10 will be studied. When the thickness of the first substrate 10 changes, the frequency characteristics change. This shows that the frequency characteristics greatly fluctuate due to variation of the thickness of the first substrate 10. The first substrate 10 is formed by polishing a single crystal substrate or forming a film in a thin film forming process. For this reason, in an actual manufacturing process, variation of the film thickness cannot be avoided. Therefore, in order to realize stable frequency characteristics as the SAW element 30, the robustness must be raised with respect to the thickness of the first substrate 10.

However, the sapphire used as the second substrate 20 becomes the material having a low robustness. Below, the reason for this will be explained.

In order to raise the robustness with respect to variation of the thickness of the first substrate 10, specifically, the rate of change of frequency with respect to the change of the thickness of the first substrate 10 must be made low. Here, a mean value of the absolute values of the rates of change of the resonance frequency and antiresonance frequency when the thickness of the first substrate 10 changes is defined as the “frequency change ratio”. The frequency change ratio is represented by the following numerical expression:

(Δf/f)/(Δt/t)=(IΔfr/fr)/(Δt/t)+(Δfa/fa)/(Δt/t))/2

Here, “f” designates a frequency, fr a resonance frequency, fa an antiresonance frequency, and “t” the thickness of the first substrate 10. Further, A indicates the amount of change of the same. The unit of the frequency change ratio is dimensionless. However, it will be indicated by %/% for easy understanding. When this frequency change ratio is small, the SAW element becomes high in robustness.

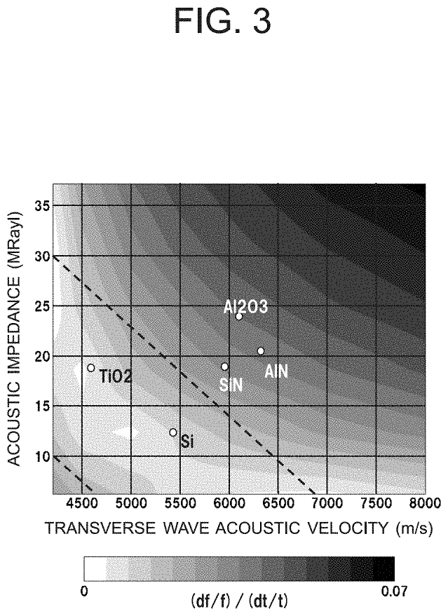

The results of simulation of this frequency change ratio by changing the material parameters of the second substrate 20 will be shown in FIG. 3. In FIG. 3, an abscissa shows the acoustic velocity V (unit: m/s) of the transverse bulk wave propagating in the second substrate 20, and an ordinate shows an acoustic impedance I (unit: MRayl) of the second substrate 20. This shows a contour map of the frequency change ratio.

As apparent also from FIG. 3, when using sapphire (Al₂O₃) as the second substrate 20, it can be confirmed that the frequency change ratio becomes relatively high.

Here, according to the SAW element 1 in the present disclosure, the intermediate layer 50 is arranged just under the first substrate 10. Due to existence of this intermediate layer 50, even in a case where sapphire having a possibility of making the frequency change ratio relatively high as explained above is used for the second substrate 20, the robustness with respect to the thickness of the first substrate 10 can be raised. Below, the mechanism thereof will be explained.

In the first substrate 10 having a thickness less than 2p, when becoming thick, the amount of distribution of the acoustic wave vibration of SAW in the first substrate 10 becomes large, therefore the frequency shifts to a lower frequency side. On the other hand, when the thickness of the first substrate 10 becomes thick, the amount of distribution of SAW in the intermediate layer 50 and second substrate 20 is reduced.

Here, the intermediate layer 50, as explained before, becomes slower in acoustic velocity than the first substrate 10. Due to the reduction of the amount of distribution of SAW in such an intermediate layer 50 having a slow acoustic velocity, the frequency characteristics of the entire SAW element 30 shift to a higher frequency side.

Further, the second substrate 20, as explained before, becomes faster in acoustic velocity than the first substrate 10. Due to the reduction of the amount of distribution of SAW in such a second substrate 20 having a fast acoustic velocity, the frequency characteristics of the entire SAW element 30 shift to a lower frequency side.

By employing a configuration stacking the three components on each other, as the SAW element 30 as a whole, the changes of frequency characteristics are cancelled out by each other, therefore frequency change can be suppressed. Here, when the first substrate 10 is thin, the reduction of frequency due to the thickness change becomes large. Therefore, by introducing the intermediate layer 50 made of a material having a slower acoustic velocity than the second substrate 20 like the first substrate 10, the reduction of frequency can be eased. This can be said to make it possible to obtain the same effect as raising the robustness by making the first substrate 10 thicker while maintaining the characteristics of the bulk wave spurious as they are.

The effect by insertion of such an intermediate layer 50 will be studied.

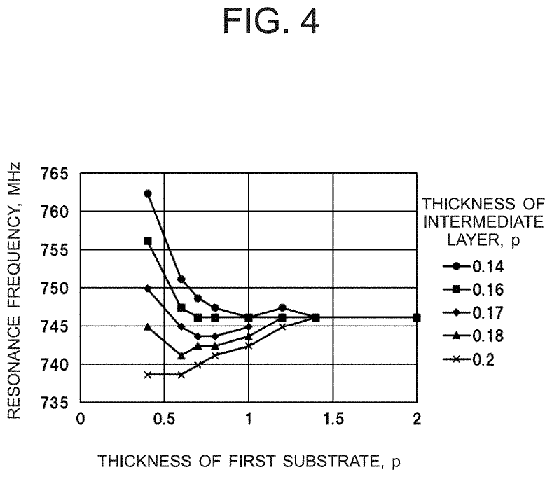

FIG. 4 shows the state of the change of the value of the resonance frequency fr of the SAW element 30 at the time when the thickness of the intermediate layer 50 and the thickness of the first substrate 10 are made different. In FIG. 4, the abscissa shows the thickness ratio of the first substrate 10 with respect to the pitch, and the ordinate shows the frequency (unit: MHz).

FIG. 4 shows the results of simulation of the state of the change of the resonance frequency at each thickness by using Ta₂O₅ as the intermediate layer 50 and making the thickness different in a range of 0.14p to 0.20p. As apparent from FIG. 4, even if there is the intermediate layer 50, the resonance frequency changes in accordance with the change of the thickness of the first substrate 10. However, it can be confirmed that a region where the rate of change becomes small exists. In more detail, it is seen that there is a thickness of the intermediate layer 50 capable of making the frequency change ratio small in accordance with the thickness of the first substrate 10.

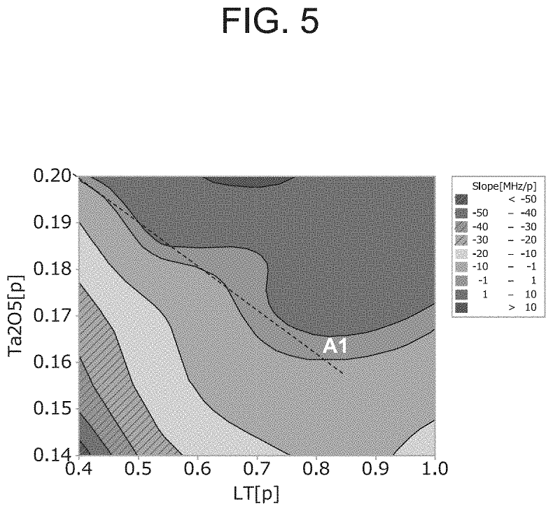

Predicated on the results of simulation shown in FIG. 4, FIG. 5 shows the state of the frequency change in the case where the thickness of the first substrate 10 and the thickness of the intermediate layer 50 were made different by contour lines. As shown in FIG. 5, in a region where the thickness of the first substrate 10 is less than 0.9p at the largest, as confirmed, the thicker the first substrate 10, the smaller the thickness of the intermediate layer 50 capable of making the frequency change fall in a range of ±1 MHz/p linearly. Note that, in FIG. 5, the region where the frequency change can be made fall into the range of ±1 MHz/p is defined as “A1”. By a relationship that the thickness of the first substrate 10 and the thickness of the intermediate layer 50 are positioned in the region A1 in FIG. 5, it becomes possible to realize excellent electrical characteristics with small frequency fluctuation.

Here, it is seen that, in a region where the thickness of the first substrate 10 is 0.9p or more, the thickness of the intermediate layer 50 in the region A1 does not become low even if the first substrate 10 becomes thick, therefore the correlation becomes low. This is considered to be caused by increase of the thickness of the first substrate 10 and reduction of the ratio of the SAW which leaks to the outer side of the first substrate 10.

When predicated on the above explanation, in a region where the thickness “D” of the first substrate 10 is 0.85p or less, the thickness of the intermediate layer 50 may be within a range of −0.0925×D±0.237p±0.005p in conversion of the pitch ratio as well. The center value in such a range is indicated by a broken line in FIG. 5.

Note that, as apparent also from FIG. 5, there is a region where the width of an area capable of making the frequency change fall into the range of ±1 MHz/p becomes idiosyncratically large. Specifically, when the thickness of the first substrate 10 is made 0.68p±0.02p and the thickness of the intermediate layer 50 is made 0.18p±0.005p, the robustness can be made higher. Further, when focused on raising the robustness with respect to the thickness of the intermediate layer 50, the thickness of the first substrate 10 may be made 0.65p to 0.75p as well. In this case, the width of the intermediate layer 50 capable of making the frequency change fall into the range of ±1 MHz/p can be made larger. In the same way, when focused on raising the robustness with respect to the fluctuation of the thickness of the first substrate 10, the thickness of the intermediate layer 50 may be made 0.18p to 0.185p. In that case, the width of the thickness of the first substrate 10 capable of making the frequency change fall into the range of ±1 MHz/p can be rapidly made larger. In particular, when the thickness of the intermediate layer 50 is 0.183p to 0.185p, the width of the thickness of the first substrate 10 capable of making the frequency change fall into the range of ±1 MHz/p can be made as large as 0.55p to 0.72p.

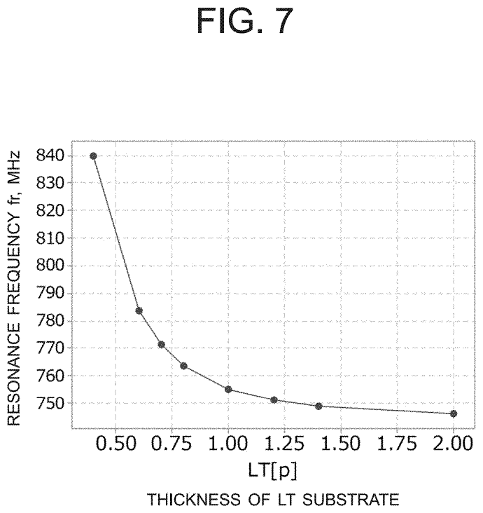

Note that, when there is no intermediate layer 50, it is confirmed that the fluctuation of the resonance frequency is larger than that in a case where the thickness of the intermediate layer 50 is 0.14p in FIG. 4. Specifically, FIG. 7 shows the state of change of the resonance frequency with respect to the thickness of the first substrate for an acoustic wave element which is not provided with the intermediate layer 50 and is formed by directly bonding the first substrate made of LT and the second substrate made of sapphire to each other. In FIG. 7, the abscissa shows the thickness of the first substrate with respect to the pitch (thickness normalized by pitch), and the ordinate shows the resonance frequency (unit: MHz).

As apparent from FIG. 7, when the thickness of the first substrate is less than 1p, the frequency change ratio is high. Specifically, in a region where the thickness of the first substrate is 0.6p to 0.8p, the amount of frequency change when the thickness of the first substrate changed by 0.1 μm was 3.7 MHz. Contrary to this, it could be confirmed that, according to the SAW element 30, the amount was 0.23 MHz in the same thickness range, therefore the robustness became 15 times or more higher.

Note that, when using a material having a high acoustic velocity as the intermediate layer, the fluctuation of the resonance frequency became larger with the same mechanism as that in the case where the second substrate was directly joined. From the above explanation, by provision of the intermediate layer 50 having a low acoustic velocity, for the first time, a SAW element 30 having a high robustness with respect to the thickness variation of the first substrate 10 can be provided.

(Modification of SAW Element 30)

In the example explained above, the only restriction was that the thickness of the first substrate 10, including the intermediate layer 50, be less than 2p. However, the thickness may be made 0.55p to 0.85p as well.

As apparent also from FIG. 4, the thicker the first substrate 10, the smaller the frequency change. On the other hand, when focusing on the characteristics as the resonator, the smaller the thickness of the first substrate 10, the smaller the loss. For this reason, the thickness of the first substrate 10 may be made 1p or less. Further, when the thickness is made 0.85p or less, the maximum phase of the resonator can be made 88 deg or more.

On the other hand, when the thickness of the first substrate 10 is 0.4p or less, the difference between the resonance frequency and the antiresonance frequency becomes smaller, therefore there is a possibility that a sufficient frequency difference no longer can be secured. Further, when the thickness becomes 0.55p or more, the region A1 becomes broader, therefore the robustness with respect to the thickness of the intermediate layer 50 can also be raised.

When taking them into account, the thickness of the first substrate 10 may be made 0.55p to 0.85p. In this case, the characteristics as the resonator are high. In addition, as apparent also from FIG. 4, the region becomes high in robustness also with respect to the thickness of the intermediate layer 50. That is, a SAW element 30 having a high tolerance with respect to both of the thickness fluctuation of the first substrate 10 and the thickness fluctuation of the intermediate layer 50 and having a small frequency change can be provided.

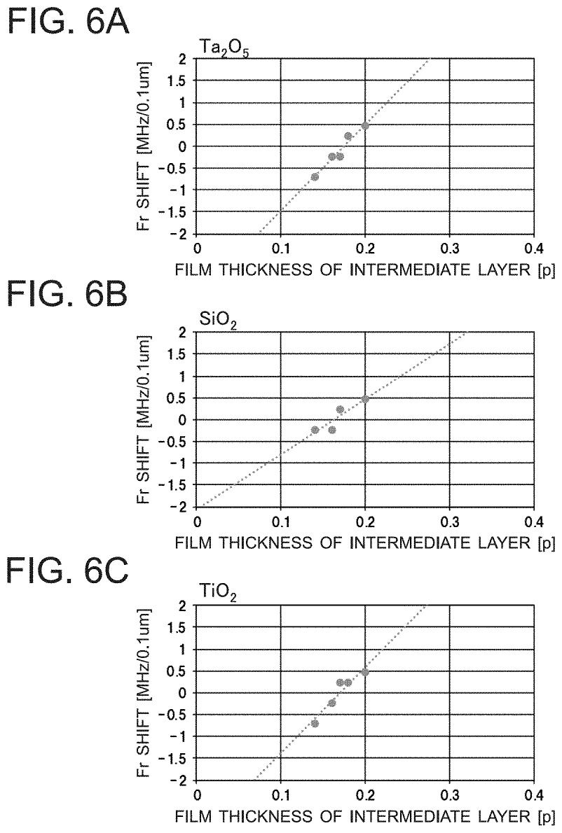

The thickness of the intermediate layer 50 when using the first substrate 10 having such a thickness will be studied. FIGS. 6A to 6C are graphs showing the relationships between the thickness of the intermediate layer 50 and the amount of shift of the resonance frequency. The thickness of the first substrate 10 is made within the range explained above. Further, the amount of shift means the amount of change of the resonance frequency at the time when the thickness of the first substrate 10 is made different by 0.1 μm (that is 0.037p).

In FIGS. 6A to 6C, the abscissas show the thicknesses of the intermediate layer 50 with respect to the pitch, and the ordinates show the amounts of shift of the resonance frequency when the thickness of the first substrate 10 is made different by 0.1 μm. Further, FIG. 6A shows a case where use is made of Ta₂O₅ as the intermediate layer, FIG. 6B shows a case where use is made of Si₂, and FIG. 6C shows a case where use is made of TiO₂.

As apparent from FIGS. 6A to 6C, it could confirmed that when the thickness of the first substrate 10 is 0.55p to 0.85p in range, even in a case where the material of the intermediate layer 50 was made different, the thickness where the amount of shift became zero became about 0.0.18p. Further, the thickness range of the intermediate layer 50 making the amount of shift within the range of ±1 MHz/p becomes 0.12p to 0.23p in the case of Ta₂O₅, becomes 0.08p to 0.24p in the case of Si₂, and becomes 0.12p to 0.22p in the case of TiO₂. From the above explanation, the thickness of the intermediate layer 50 may be made 0.08p to 0.24p as well. More preferably, it may be 0.12p to 0.22p. Further, where it is made 0.15p to 0.21p, a SAW element 30 with a further smaller frequency change can be provided.

Note that, as the material of the intermediate layer 50, when using silicon oxide, even if the film thickness of the intermediate layer 50 changed, the ratio of change of the amount of frequency shift was small. That is, the inclination of the line segment in FIG. 6 was small. From this, use may be made of silicon oxide too in order to raise the robustness with respect to the thickness of the intermediate layer 50.

On the other hand, from the viewpoint of the resonator characteristic Δf, use may be made of tantalum oxide as the intermediate layer 50. In that case, an effect of reduction of Δf can be expected, therefore a steeper filter characteristic can be obtained.

### REFERENCE SIGNS LIST

1: composite substrate
10: first substrate
20: second substrate
30: acoustic wave element
31: IDT electrode
50: intermediate layer

1. An acoustic wave element comprising:
an IDT electrode which comprises a plurality of electrode fingers and excites a surface acoustic wave,
a first substrate which is made of a piezoelectric crystal on an upper surface of which the IDT electrode is located and has a thickness less than 2 times “p” defined as a repetition interval of the plurality of electrode fingers,
an intermediate layer which comprises a first surface and a second surface, has the first surface joined to a lower surface of the first substrate, and is made of a material having a slower transverse wave acoustic velocity than the first substrate, and
a second substrate made of sapphire which is joined to the second surface.

2. The acoustic wave element according to claim 1, wherein the intermediate layer contains, as a principal ingredient, any of titanium oxide, tantalum oxide, and silicon oxide.

3. The acoustic wave element according to claim 1, wherein the first substrate is an X-propagation and rotated Y-cut lithium tantalate single crystal.

4. The acoustic wave element according to claim 1, wherein the intermediate layer has a thickness of 0.08p to 0.24p.

5. The acoustic wave element according to claim 4, wherein the first substrate has a thickness of 0.55p to 0.85p.

6. The acoustic wave element according to claim 1, wherein when a thickness of the first substrate is “D”, D is 0.85p or less, and a thickness of the intermediate layer is within a range of −0.0925×D+0.237p±0.005p.

7. The acoustic wave element according to claim 1, wherein a thickness of the first substrate is 0.68p to 0.72p, and a thickness of the intermediate layer is 0.175p to 0.185p.

8. The acoustic wave element according to claim 1, wherein a thickness of the intermediate layer is 0.183p to 0.185p, and a thickness of the first substrate is 0.55p to 0.72p.

9. The acoustic wave element according to claim 1, wherein a thickness of the first substrate and a thickness of the intermediate layer satisfy relationships of a region indicated by A1 in FIG. 5.
